(19) United States
(12) Patent Application Publication
(10) Pub. No.: US 2013/0322026 A1
(43) Pub. Date: Dec. 5, 2013

(54) ELECTRONIC DEVICE

(71) Applicants: Yi-Chieh Huang, Taipei City (TW); Chih-Chiang Wang, Taipei City (TW); Ming-Wang Lin, Taipei City (TW); Hui-Lian Chang, Taipei City (TW)

(72) Inventors: Yi-Chieh Huang, Taipei City (TW); Chih-Chiang Wang, Taipei City (TW); Ming-Wang Lin, Taipei City (TW); Hui-Lian Chang, Taipei City (TW)

(73) Assignee: COMPAL ELECTRONICS, INC., Taipei City (TW)

(21) Appl. No.: 13/909,112

(22) Filed: Jun. 4, 2013

Related U.S. Application Data
(60) Provisional application No. 61/654,958, filed on Jun. 4, 2012.

(51) Int. Cl. H05K 7/02

(52) U.S. Cl. CPC H05K 7/02
USPC 361/728

(57) ABSTRACT

An electronic device of the invention includes a base and a touch-vibration module. The base has an opening. The touch-vibration module includes a supporting bracket, a mass balancing element, a vibrating unit and a touch unit. The supporting bracket is connected to the base at the opening of the base. The mass balancing element is disposed at the supporting bracket. The vibrating unit is disposed at the supporting bracket. The touch unit is disposed at the supporting bracket and the vibrating unit is located between the supporting bracket and the touch unit.

### CROSS-REFERENCE TO RELATED APPLICATION

This application claims the priority benefits of U.S. provisional application Ser. No. 61/654,958, filed on Jun. 4, 2012. The entirety of the above-mentioned patent applications is hereby incorporated by reference herein and made a part of this specification.

### BACKGROUND OF THE INVENTION

1. Field of the Invention

The invention generally relates to an electronic device, and more particularly, to an electronic device (such as a notebook computer) with a touch-vibration module.

2. Description of Related Art

Due to the decreasing production cost of the notebook computer in addition to its smaller volume and weight, the desktop computers are gradually substituted by the notebook computers. In order to directly move the cursor on the display by a user without a mouse, a touch pad and a plurality of keys adjacent to the touch pad are usually employed and disposed under the keyboard of the notebook computer where the touch pad and the keys are configured to simulate the operation of a mouse. With such a configuration, i.e., a notebook computer is equipped with a touch pad, the mouse is not necessarily employed, but the operation of the mouse still can be done through the touch pad and the adjacent keys.

For some kinds of notebook computers, the keys adjacent to the touch pad are integrated to a position under the touch pad. At the time, whenever a specific area of the touch pad is pressed, a corresponding pressing signal is generated. As a result, the appearance visual effect of the notebook computer without disposing the above-mentioned original keys beside the touch pad is advanced. In addition, the touch pad of the notebook computer can incorporate a vibrating function, so that a vibration is produced according to a control signal and transmitted to the hand of the user via the touch pad.

### SUMMARY OF THE INVENTION

Accordingly, the invention is directed to an electronic device for providing functions of touching, pressing and vibrating.

An electronic device of the invention includes a base and a touch-vibration module. The base has an opening. The touch-vibration module includes a supporting bracket, a mass balancing element, a vibrating unit and a touch unit. The supporting bracket is connected to the base at the opening of the base. The mass balancing element is disposed at the supporting bracket. The vibrating unit is disposed at the supporting bracket. The touch unit is disposed at the supporting bracket and the vibrating unit is located between the supporting bracket and the touch unit.

In an embodiment of the invention, the sum of mass of the supporting bracket and the mass balancing element is greater than the mass of the touch unit.

In an embodiment of the invention, there is a gap between the vibrating unit and the mass balancing element.

In an embodiment of the invention, there is a gap between the touch unit and the mass balancing element.

In an embodiment of the invention, the supporting bracket and the mass balancing element are integrally formed.

In an embodiment of the invention, the touch-vibration module further includes another vibrating unit disposed at the supporting bracket, in which the vibrating units are respectively located at both sides of the mass balancing element.

In an embodiment of the invention, the touch-vibration module further includes a pressed unit disposed on the touch unit.

In an embodiment of the invention, the base has a protrusive point, and when the supporting bracket under an external force moves relatively to the base, the pressed unit moves towards the protrusive point and is pressed by the protrusive point.

In an embodiment of the invention, the protrusive point goes through the supporting bracket and the mass balancing element to press the pressed unit.

Based on the depiction above, the invention adopts a mass balancing element disposed at the supporting bracket, so that the vibration produced by the vibrating unit can be transmitted to the touch unit as much as possible to advance the vibrating effect.

Other features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

FIG. 1 is a perspective view of an electronic device according to an embodiment of the invention.

FIG. 2 is a schematic view illustrating the touch-vibration module of FIG. 1 is separated from the base of the electronic device.

FIG. 3 is a top exploded perspective view of the touch-vibration module in FIG. 2.

FIG. 4 is a—bottom exploded perspective view of the touch-vibration module in FIG. 2.

FIG. 5A is a cross-sectional view of the touch-vibration module taken along line A-A in FIG. 2.

FIG. 5B is a partial enlarged view of the portion 5B of FIG. 5A.

FIG. 6A is a cross-sectional view of the touch-vibration module taken along line B-B in FIG. 1.

FIG. 6B is a partial enlarged view of the portion 6B of FIG. 6A.

### DESCRIPTION OF THE EMBODIMENTS

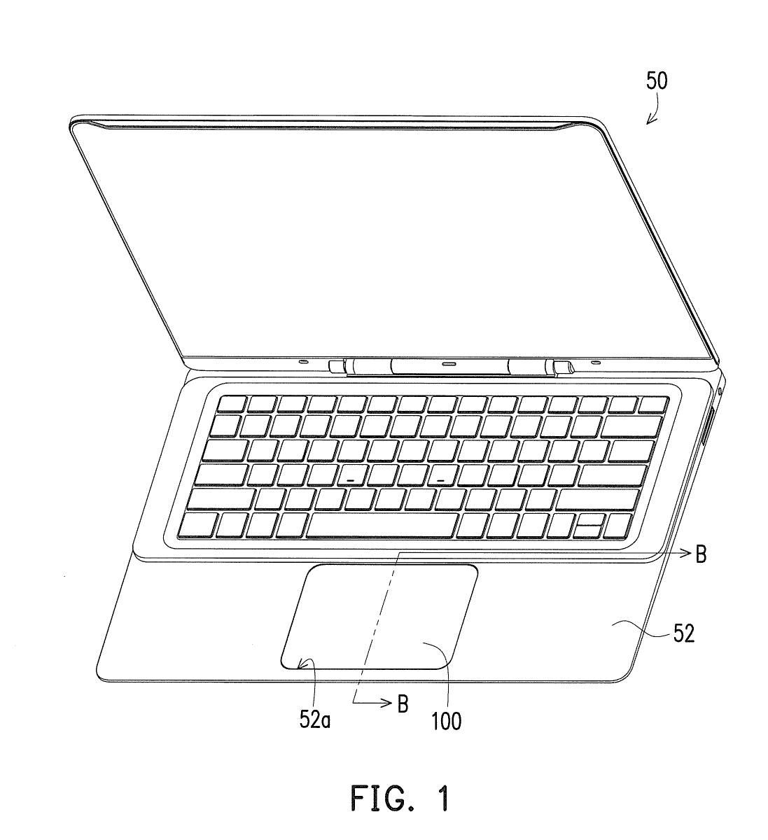

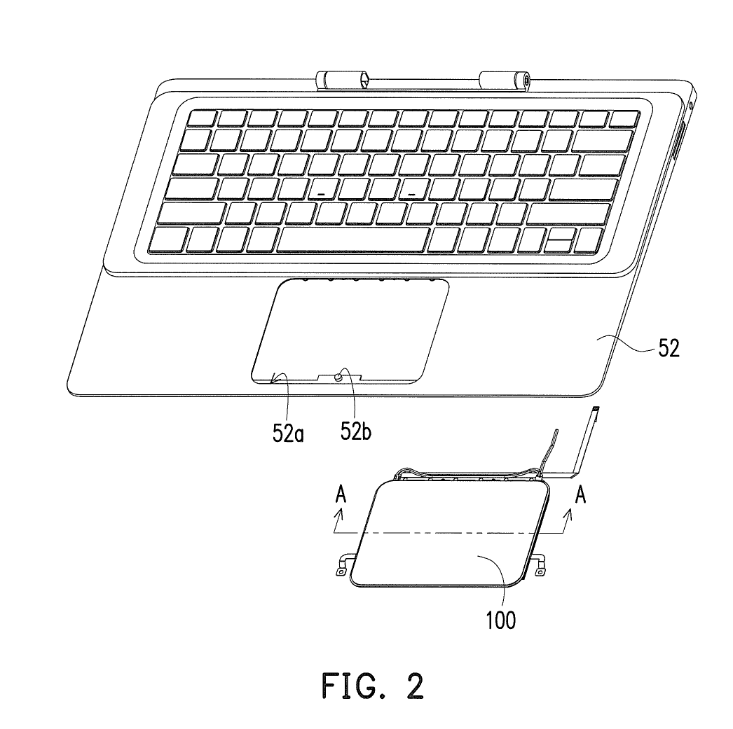

FIG. 1 is a perspective view of an electronic device according to an embodiment of the invention, and FIG. 2 is a schematic view illustrating the touch-vibration module of FIG. 1 is separated from the base of the electronic device. Referring to FIGS. 1 and 2, an electronic device 50 in the embodiment is, for example, a notebook computer. The electronic device 50 has a base 52 and a touch-vibration module 100. The base 52 has an opening 52a. The touch-vibration module 100 includes a supporting bracket 110, a mass balancing element 120, one or multiple vibrating units 130 and a touch unit 140.

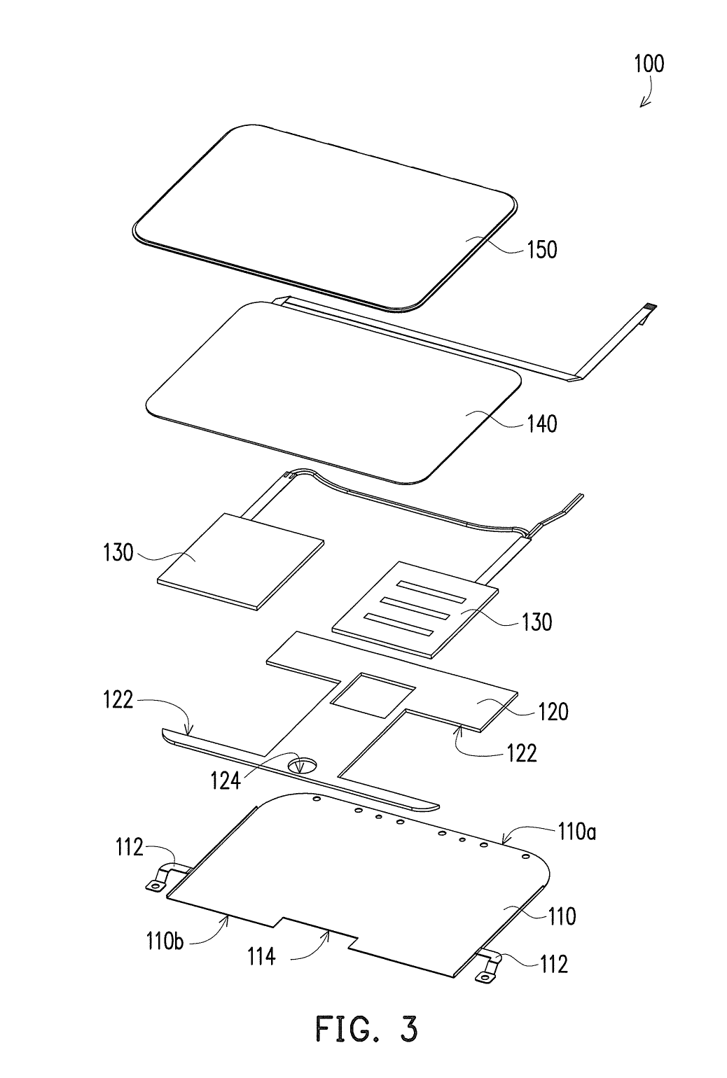

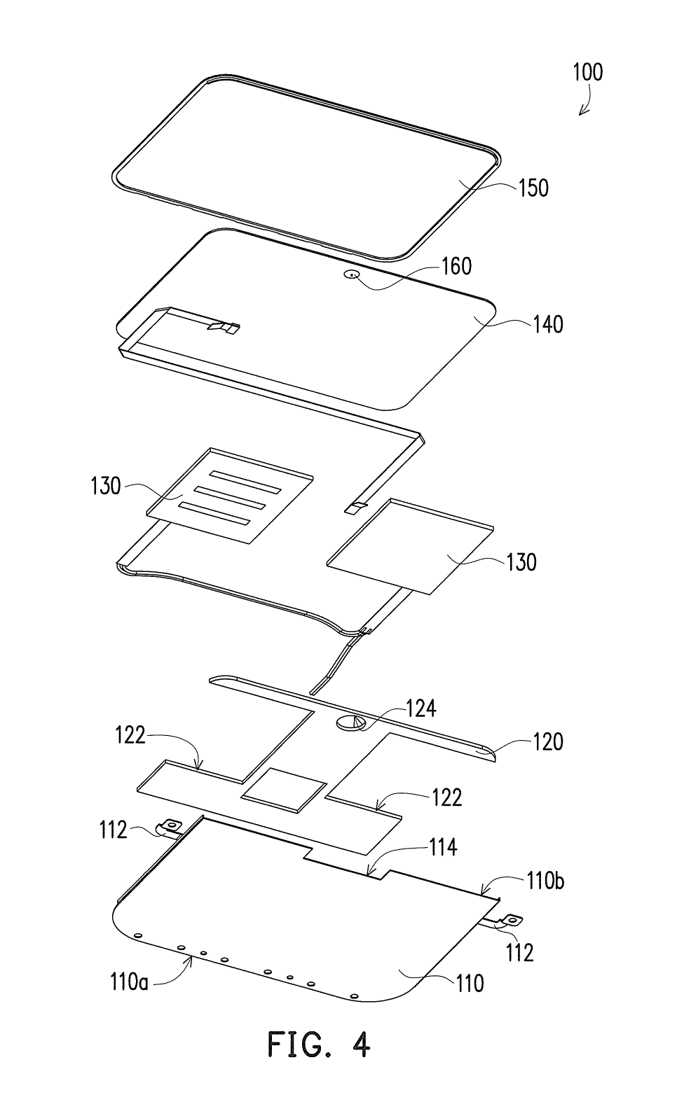

FIG. 3 is a top exploded perspective view of the touch-vibration module in FIG. 2, and FIG. 4 is a bottom exploded perspective view of the touch-vibration module in FIG. 2. Referring to FIGS. 2-4, the supporting bracket 110 is connected to the base 52 at the opening 52a of the base 52. In the embodiment, the supporting bracket 110 has a fixing side 110a and a free side 110b, in which the fixing side 110a is configured to be fixed to a side of the opening 52a. The fixing side 110a is fastened to the base 52 by using screws. The supporting bracket 110 may be a metallic part. In the embodiment, the supporting bracket 110 has two elastic parts 112, and the two elastic parts 112 extend out and are fastened to the base 52 to ensure the predetermined position of the supporting bracket 110 relatively to the base 52.

Referring to FIGS. 2-4 again, the mass balancing element 120 is disposed at the supporting bracket 110 for damping the vibration transmitted to the supporting bracket 110. The mass balancing element 120 may be a metallic part. In another unshown embodiment, the supporting bracket 110 and the mass balancing element 120 may be integrally formed, i.e., only one single part is used to provide the supporting function and the mass balancing function.

In FIGS. 2-4, the vibrating unit 130 is disposed at the supporting bracket 110, the touch unit 140 is also disposed at the supporting bracket 110, and the vibrating unit 130 is located between the supporting bracket 110 and the touch unit 140. In the embodiment, the sum of mass of the supporting bracket 110 and the mass balancing element 120 may be greater than the mass of the touch unit 140. Thus, when the vibration produced by the vibrating unit 130 is transmitted to the touch unit 140, the touch unit 140 may have a vibration with larger vibration amplitude to enhance the vibrating effect. In addition, the vibrating unit 130 may be a thin-film-type vibration module and the touch unit 140 may be a thin-film-type touch module.

The touch-vibration module 100 may further include a decorative panel 150 disposed on the touch unit 140 to allow the user touching it. In the embodiment, the sum of mass of the supporting bracket 110 and the mass balancing element 120 may be greater than the sum of mass of the touch unit 140 and the decorative panel 150. Thus, when the vibration produced by the vibrating unit 130 is transmitted to the touch unit 140, the touch unit 140 and/or the decorative panel 150 may have a vibration with larger vibration amplitude to enhance the vibrating effect.

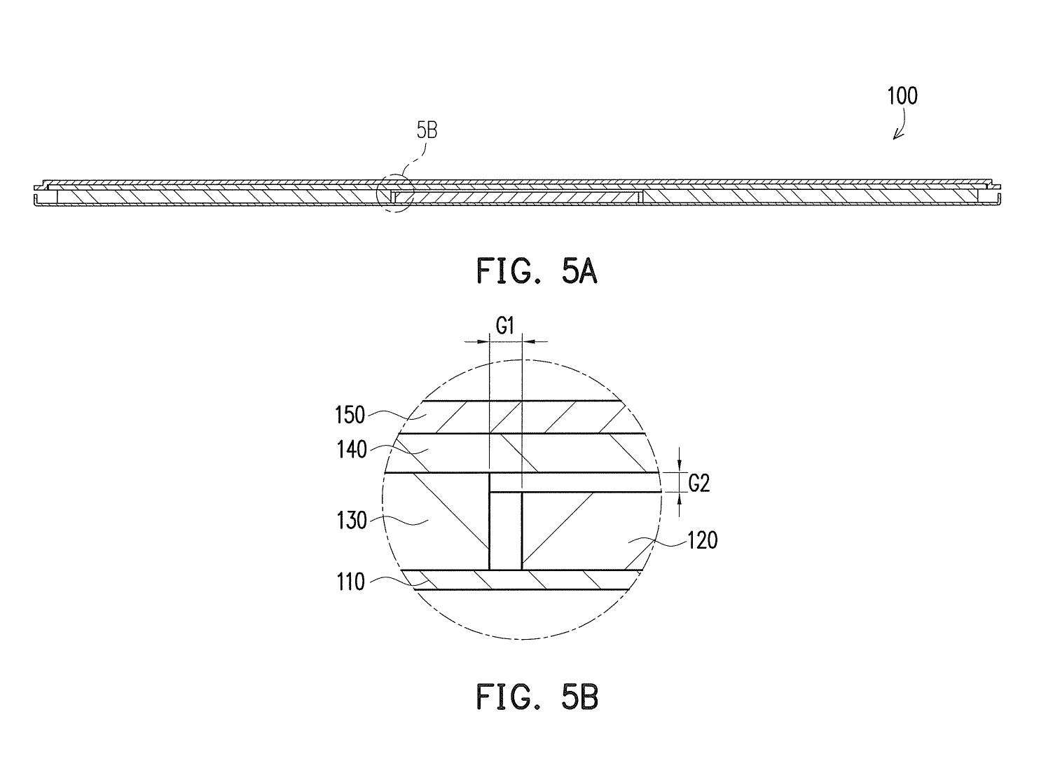

FIG. 5A is a cross-sectional view of the touch-vibration module taken along line A-A in FIG. 2 and FIG. 5B is a enlarged view of the portion 5B of FIG. 5A. Referring to FIGS. 2, 5A and 5B, in order to avoid the vibration produced by the vibrating unit 130 from directly being transmitted to the mass balancing element 120, there is a gap G1 between the vibrating unit 130 and the mass balancing element 120 by design for isolating the direct transmission of the vibration. In the same way, in order to avoid the vibration produced by the vibrating unit 130 from directly being transmitted to the touch unit 140, there is another gap G2 between the touch unit 140 and the mass balancing element 120 by design for isolating the direct transmission of the vibration.

Referring to FIGS. 2, 5A and 5B, in the embodiment, the touch-vibration module 100 further includes another vibrating unit 130 disposed at the supporting bracket 110 as well. It should be noted that the vibrating units 130 are respectively located at both sides of the mass balancing element 120. In more details, the mass balancing element 120 has two recesses 122, and the recesses 122 may respectively accommodate the vibrating units 130. In another unshown embodiment, the recesses 122 may be openings as well.

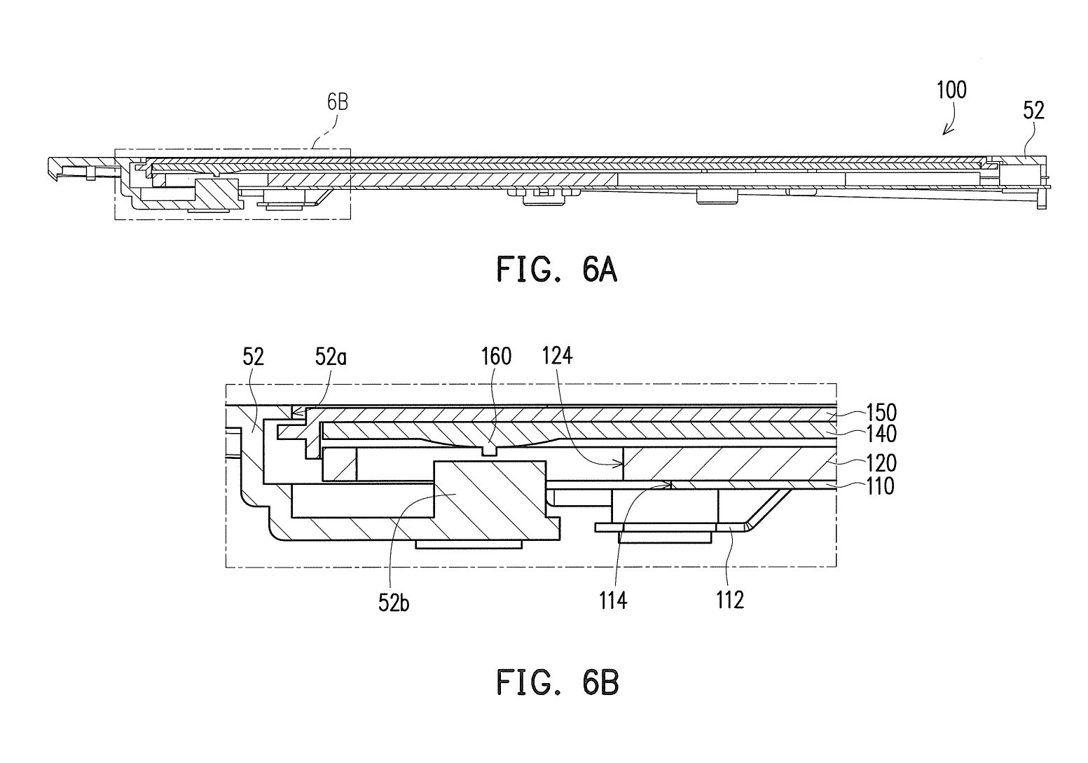

FIG. 6A is a cross-sectional view of the touch-vibration module taken along line B-B in FIG. 1, and FIG. 6B is a enlarged view of the portion 6B of FIG. 6A. Referring to FIGS. 2, 4, 6A and 6B, the touch-vibration module 100 herein further includes a pressed unit 160 disposed on the touch unit 140. In the embodiment, the pressed unit 160 may be a metal dome. For producing a pressing signal by pressing the pressed unit 160, the base 52 has a protrusive point 52b, as shown by FIGS. 2 and 6A. When the supporting bracket 110 under an external force moves relatively to the base 52, the pressed unit 160 moves towards the protrusive point 52b and is pressed by the protrusive point 52b. Specifically, when the free side 110b of the supporting bracket 110 swings relatively to the fixing side 110a, the pressed unit 160 moves towards the protrusive point 52b and is pressed by the protrusive point 52b.

In the embodiment, the protrusive point 52b goes through the supporting bracket 110 and the mass balancing element 120 to press down the pressed unit 160, as shown in FIG. 6B. Specifically, the supporting bracket 110 has a recess 114 and the mass balancing element 120 has a through hole 124. The protrusive point 52b goes through the recess 114 and the through hole 124 to press down the pressed unit 160.

In summary, the invention adopts a mass balancing element disposed at the supporting bracket, so that the vibration produced by the vibrating unit can be transmitted to the touch unit as much as possible to advance the vibrating effect. In addition, there is a gap between the vibrating unit and the mass balancing element, and there is another gap between the touch unit and the mass balancing element, both which can avoid the vibration produced by the vibrating unit from directly being transmitted to the mass balancing element and the touch unit. Moreover, the sum of mass of the supporting bracket and the mass balancing element is greater than the mass of the touch unit and/or the decorative panel. Thus, when the vibration produced by the vibrating unit is transmitted to the touch unit, the touch unit can have a vibration with larger vibration amplitude to enhance the vibrating effect.

It will be apparent to those skilled in the art that the descriptions above are several preferred embodiments of the invention only, which does not limit the implementing range of the invention. Various modifications and variations can be made to the structure of the invention without departing from the scope or spirit of the invention. The claim scope of the invention is defined by the claims hereinafter.

What is claimed is:

1. An electronic device, comprising:
a base, having an opening; and
a touch-vibration module, comprising:
a supporting bracket, connected to the base at the opening of the base;
a mass balancing element, disposed at the supporting bracket;
a vibrating unit, disposed at the supporting bracket; and
a touch unit, disposed at the supporting bracket, wherein the vibrating unit is located between the supporting bracket and the touch unit.

2. The electronic device as claimed in claim 1, wherein the sum of mass of the supporting bracket and the mass balancing element is greater than the mass of the touch unit.

3. The electronic device as claimed in claim 1, wherein there is a gap between the vibrating unit and the mass balancing element.

4. The electronic device as claimed in claim 1, wherein there is a gap between the touch unit and the mass balancing element.

5. The electronic device as claimed in claim 1, wherein the supporting bracket and the mass balancing element are integrally formed.

6. The electronic device as claimed in claim 1, wherein the touch-vibration module further comprises:
another vibrating unit, disposed at the supporting bracket, wherein the vibrating units are respectively located at both sides of the mass balancing element.

7. The electronic device as claimed in claim 1, wherein the touch-vibration module further comprises:
a pressed unit, disposed on the touch unit.

8. The electronic device as claimed in claim 7, wherein the base has a protrusive point, and when the supporting bracket under an external force moves relatively to the base, the pressed unit moves towards the protrusive point and is pressed by the protrusive point.

9. The electronic device as claimed in claim 8, wherein the protrusive point goes through the supporting bracket and the mass balancing element to press the pressed unit.
